(19) United States
(12) Patent Application Publication
(10) Pub. No.: US 2025/0311087 A1
(43) Pub. Date: Oct. 2, 2025

(54) CONTINUOUS FLOW WATER HEATER AND HEATING PLATE FOR A CONTINUOUS FLOW WATER HEATER

(71) Applicant: BorgWarner Inc., Auburn Hills, MI (US)

(72) Inventor: Sisay Tadele, Friolzheim (DE)

(21) Appl. No.: 19/086,825

(22) Filed: Mar. 21, 2025

(30) Foreign Application Priority Data
Mar. 28, 2024 (DE) 10 2024 108 924.5

(51) Int. Cl. H05K 1/02; F24H 9/00; F24H 9/14; H01R 12/58

(52) U.S. Cl. CPC H05K 1/0212; H01R 12/585; F24H 9/0005; F24H 9/146

(57) ABSTRACT

A flow heater has a heating plate that has a metal plate, a heating conductor track, and an insulating layer between the heating conductor track and the metal plate. The heating plate is arranged in a housing and the housing encloses a flow channel for fluid to be heated, which leads from an inlet port of the housing to an outlet port of the housing. A circuit board with control electronics is provided. An electrical connector connects the heating conductor track of the heating plate electrically to the control electronics, and the electrical connector has a plastic body from which a conductor projects and extends into a hole of the circuit board. The heating plate is clamped between a clamping part of the electrical connector and an end section of the conductor projecting from the plastic body. A heating plate for such a flow heater is also described.

### RELATED APPLICATIONS

This application claims priority to DE 10 2024 108 924.5, filed Mar. 28, 2024, the entire disclosure of which is hereby incorporated herein by reference.

### BACKGROUND

This disclosure relates to a flow heater and a heating plate for a flow heater, of the type generally described in DE 10 2022 132 476 B3. The flow heater of DE 10 2022 132 476 B3 comprises an electrical connector which connects the heating plate to a circuit board with control electronics. This connector has a plastic body, from which project both ends of a metal strip. A first end section of the metal strip is soldered to the heating plate, and a second end section of the metal strip is inserted in the circuit board.

### SUMMARY

This disclosure teaches a way in which the production of a flow heater of the type referred to above can be simplified.

In a flow heater of this disclosure, an electrical contact with the heating plate is established by clamping the heating plate between a clamping part of the electrical connector and an end section of a conductor projecting from the plastic body of the electrical connector. This has the advantage of avoiding a soldered joint between the conductor leading to the circuit board and the heating plate. This simplifies the production, and allows any production tolerances to be compensated for by simple means. In addition, a longer service life of the flow heater can be achieved, since an electrical contact established by clamping is generally stronger and more reliable than a soldered connection.

The clamping part may be formed by the plastic body of the electrical connector. Greater clamping forces can be achieved if the clamping part contains sheet metal, for example, by embedding a separate clamping sheet in the plastic body, or if a clamping section branches off from the conductor, and the heating plate is clamped between this clamping section and an end section projecting from the plastic body. However, the clamping part can also be designed as a clamping sheet that projects from the plastic body of the electrical connector. The clamping sheet can be designed in one piece with the conductor, or it can be a separate metal sheet.

The conductor can be a sheet metal part that has been manufactured using a cutting process, for example, laser cutting, water jet cutting, stamping, or precision cutting. Alternatively, the conductor can also be produced by casting or layer-building processes. The clamping sheet can be produced in the same way as the conductor.

### BRIEF DESCRIPTION OF THE DRAWINGS

The above-mentioned aspects of exemplary embodiments will become more apparent and will be better understood by reference to the following description of the embodiments taken in conjunction with the accompanying drawings, wherein:

FIG. 1 shows an embodiment of a flow heater;

FIG. 2 shows a cross-sectional view through FIG. 1;

FIG. 3 shows a cross-sectional detail of the heating plate with an electrical connector;

FIG. 4 shows from below a detail of the heating plate with an electrical connector;

FIG. 5 shows from above a detail of the heating plate with an electrical connector;

FIG. 6 shows a view of the electrical connector;

FIG. 7 shows the conductor and the clamping sheet of the electrical connector;

FIG. 8 shows a further embodiment of an electrical connector;

FIG. 9 shows the conductor and the clamping sheet of the connector shown in FIG. 8;

FIG. 10 shows a further embodiment of an electrical connector with a heating plate;

FIG. 11 shows conductors and clamping sheets of the connector shown in FIG. 10;

FIG. 12 shows a further embodiment of an electrical connector with a heating plate;

FIG. 13 shows the clamping sheets of the connector shown in FIG. 12;

FIG. 14 shows a further embodiment of an electrical connector with a heating plate;

FIG. 15 shows the conductor and the clamping sheet of the connector shown in FIG. 14; and

FIG. 16 shows a side view of the embodiment shown in FIG. 14.

### DESCRIPTION

The embodiments described below are not intended to be exhaustive or to limit the invention to the precise forms disclosed in the following description. Rather, the embodiments are chosen and described so that others skilled in the art may appreciate and understand the principles and practices of this disclosure.

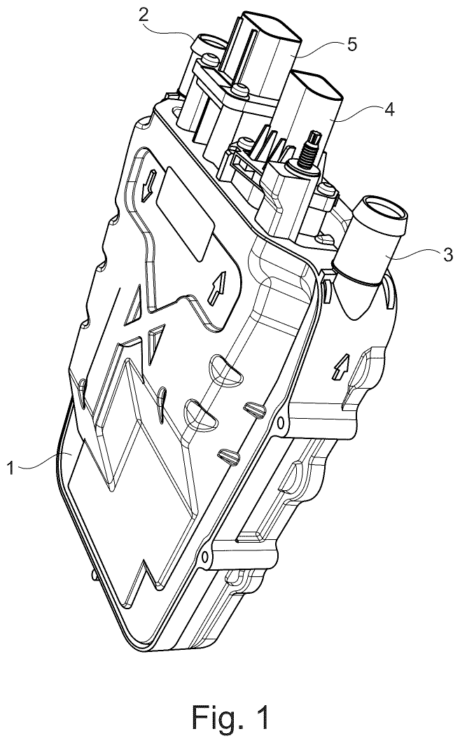

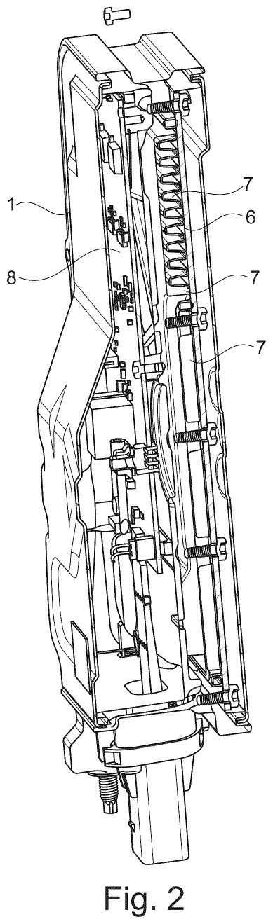

The flow heater shown in FIGS. 1 and 2 is a flow heater for liquids, e.g., water, and has a housing 1 with an inlet port 2 and an outlet port 3, together with electrical terminals 4, 5. In the housing 1 a flow channel for the fluid to be heated runs from the inlet port 2 to the outlet port 3.

The flow channel runs along a heating plate 6, which carries one or a plurality of electrical heating resistors, which are designed as heating conductor tracks. In order to improve the heat release to the fluid in the flow channel, the heating plate 6 can carry a corrugated metal sheet 7 that projects into the flow channel. The heating plate 6 is connected to a circuit board 8, which carries control electronics. In the example of embodiment shown, the heating plate 6 and the circuit board 8 are arranged one above the other and parallel to each other. However, it is also possible to arrange the circuit board 8 at an angle to the heating plate 6.

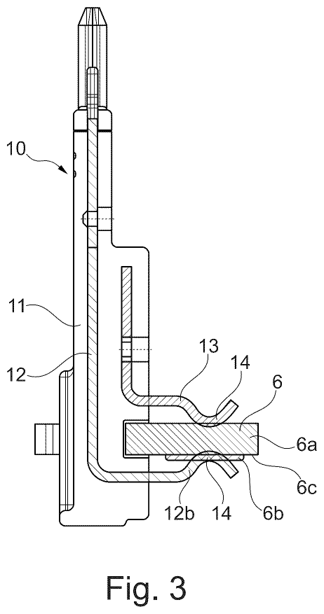

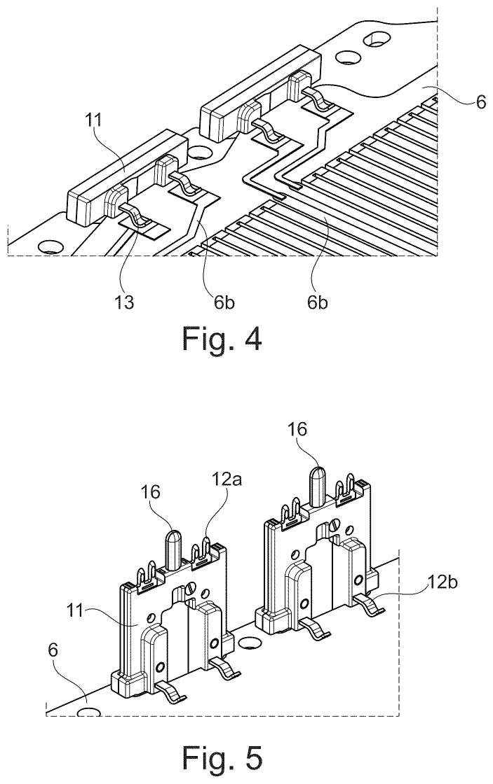

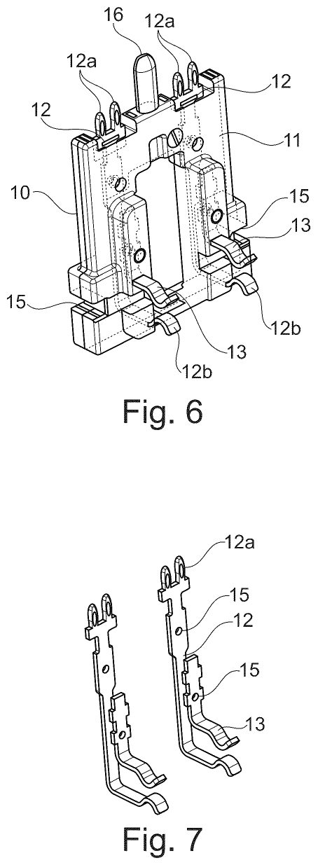

FIGS. 3 to 5 show various views of a detail of the heating plate 6 with an electrical connector 10, by means of which the heating plate 6 is connected to the circuit board 8. FIG. 6 shows the connector 10 without the heating plate.

The heating plate 6 has a metal plate 6a, made, for example, from steel or an aluminium-based alloy, as well as at least one heating conductor track 6b, and an insulation layer 6c between the metal plate 6a and the heating conductor track 6b.

The electrical connector 10, by means of which the heating conductor track 6b of the heating plate 6 is connected to the circuit board, and thus to the control electronics, has a plastic body 11, from which at least one conductor 12 projects, one end section of which is inserted into the circuit board 8. This end section of the conductor 12 is designed with a plurality of press-fit contacts 12a, for example, two press-fit contacts 12a. The other end section 12b of the conductor 12 is in contact with the heating conductor track 6b, or with one of the heating conductor tracks 6b, of the heating plate 6. The heating plate 6 is located between a clamping part 13 of the electrical connector 10 and the conductor 12. In the embodiment shown, the clamping part 13 is designed as a clamping sheet 13, which projects from the plastic body 11 of the electrical connector 10. In this embodiment, a first end section of the clamping sheet 13 is therefore in contact with the heating plate 6, while a second end section of the clamping sheet 13 is arranged in the plastic body 11.

Press-fit contacts are designed to establish an electrical connection by means of a press-fit in a metallised hole in a circuit board. Press-fit contacts must be deformed when pressed into a metallised hole. To facilitate this, the press-fit contacts in the embodiment shown have a bulging central part, and can be provided with a slot or an opening in the bulging central part. The press-fit contacts can be plated with nickel and/or tin in order to facilitate a good electrical connection with low resistance.

At its end facing towards the circuit board 8, the plastic body 11 can have one or a plurality of projections 16, for example, pins, for insertion into appropriate openings in the circuit board 8. Such a projection 16 facilitates the correct positioning of the circuit board 8 relative to the electrical connector 10, before end sections of the conductors 12, for example, in the form of press-fit contacts 12a, are pressed into appropriate openings in the circuit board 8.

In the embodiment shown, the connector 10 has a plurality of conductors 12, for example, two conductors 12. As shown in particular in FIG. 5, the connector 10 is inserted into a lateral recess in the heating plate 6. At the same time opposite edges of the heating plate 6 can sit in lateral grooves 15 of the plastic body 11 of the connector 10, and thus facilitate the mechanical connection between the heating plate 6 and the connector 10.

As shown in particular in FIG. 3, the conductor 12 and the clamping sheet in each case lie in a bent section 14 against the heating plate 6. The end section 12b of the conductor 12, like the end section of the clamping sheet, therefore has a bulge facing towards the heating plate 6. This facilitates the clamping of the heating plate 6.

In the embodiment shown, the conductor 12 is designed as a continuous metal strip, both ends of which project from the plastic body 11. Instead of a continuous metal strip, however, an assembled conductor can also be used. The conductor 12 has a main section that runs transversely to the plane of the heating plate 6, and an end section 12b that projects from the plastic body 11, extends along the heating plate 6 and abuts against the heating plate 6 in a bent section 14.

The connector 10 can be manufactured by overmolding the conductor 12 and the clamping sheet in plastic. In order to facilitate the manufacture of the electrical connector 10, the conductor 12, together with the clamping sheet, can have a passage opening 15, which enables precise positioning during the plastic overmolding procedure, in that pins of a tool engage with these openings, and are extracted after the overmolding procedure. These openings 15 can be seen in FIG. 7.

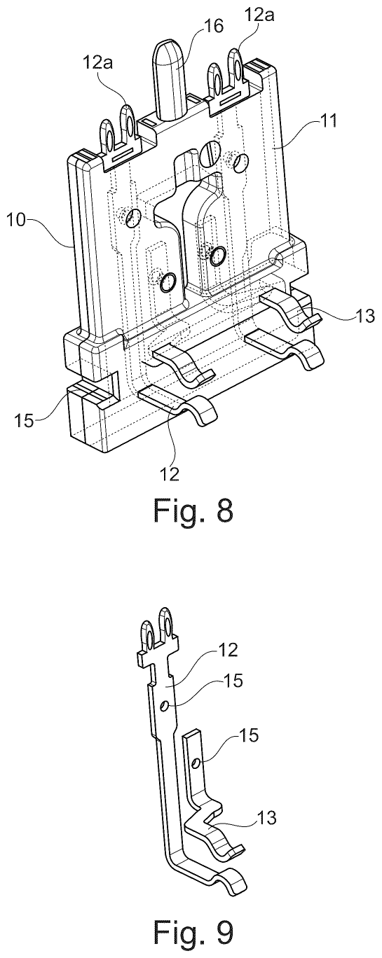

FIG. 8 shows a further example of embodiment of a connector 10, by means of which the heating conductor track of the heating plate 6, of a flow heater shown in FIGS. 1 and 2, can be connected to a circuit board. This connector 10 differs from the connector described earlier essentially only in that the conductor 12 and the clamping part 13, which in the example is shown as the clamping sheet in the plastic body 11, are no longer arranged on top of each other as shown in FIG. 7; instead, the clamping sheet has a section that is laterally offset from the end section 12b of the conductor 12, which projects from the plastic body 11, and abuts against the heating plate 6 as intended. FIG. 9 shows the conductor 12 and the clamping part 13 of the connector 10 shown in FIG. 8, in the spatial relationship that they have with each other in the connector 10.

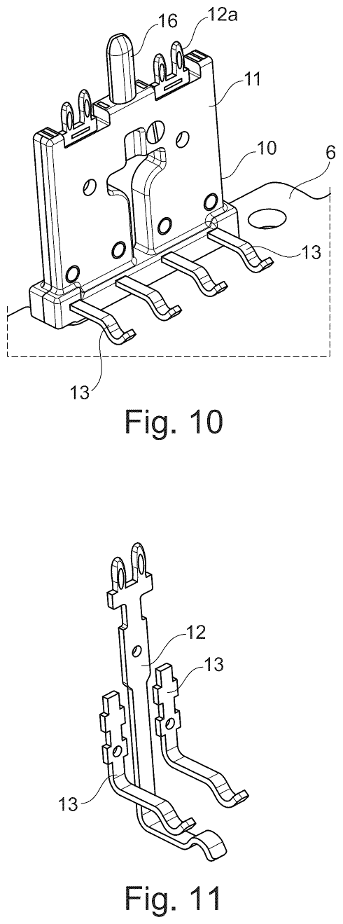

FIG. 10 shows a further embodiment of a connector 10, by means of which the heating conductor track of the heating plate 6 of the flow heater shown in FIGS. 1 and 2 can be connected to a circuit board. This connector 10 differs from the connector described above essentially only in that for each conductor 12 two clamping parts 13 in the form of clamping sheets are provided, in order to clamp the heating plate 6 between itself and the end section 12b of the conductor 12. Here the conductor 12 is arranged between the two clamping parts 13. This prevents the spring force exerted by the clamping parts 13 from generating tilting moments.

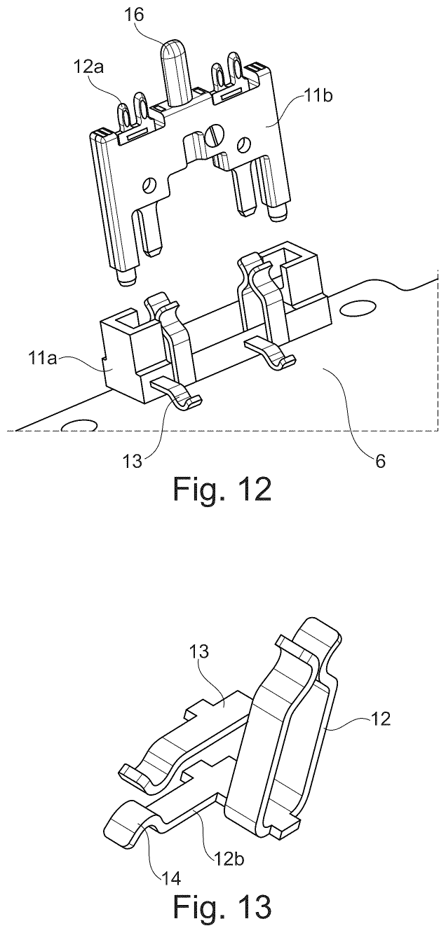

FIG. 12 shows a further embodiment of an electrical connector 10, with a detail of the heating plate 6, and FIG. 13 shows a section of the conductor 12, and the clamping parts 13 of the connector 10 shown in FIG. 12.

In the embodiment of electrical connectors 10 thus far described, the plastic body 11 is in one piece. In the embodiment shown in FIG. 12, the plastic body of the connector 10 is a multi-part body. A first body part 11a of the plastic body sits on the heating plate 6. The clamping part or parts 13, designed as clamping sheets, project from this first body part 11a, as do the end sections 12b of the conductor 12 or conductors 12, which abut against the heating plate 6. A second body part 11b is plugged into the first body part 11a. The end section 12a, or end sections 12a, of the conductor 12 project from this second body part 11b, and are inserted into the circuit board.

In the embodiment of FIGS. 12 and 13, the conductor 12 is a multi-part conductor. One part of the conductor 12 is embedded in the first body part 11a; a second part of the conductor 12 is embedded in the second body part 11b. Both parts of the conductor 12 can be made from sheet metal. One of the two conductor parts, for example, the conductor part of the first body part 11a, here forms a sprung contact receiver with two opposing sprung contact arms, while the conductor part of the other body part 11b forms a contact tongue, which is pushed into this contact receiver, and thus between these two opposing sprung contact arms, when the two body parts 11a, 11b are plugged together.

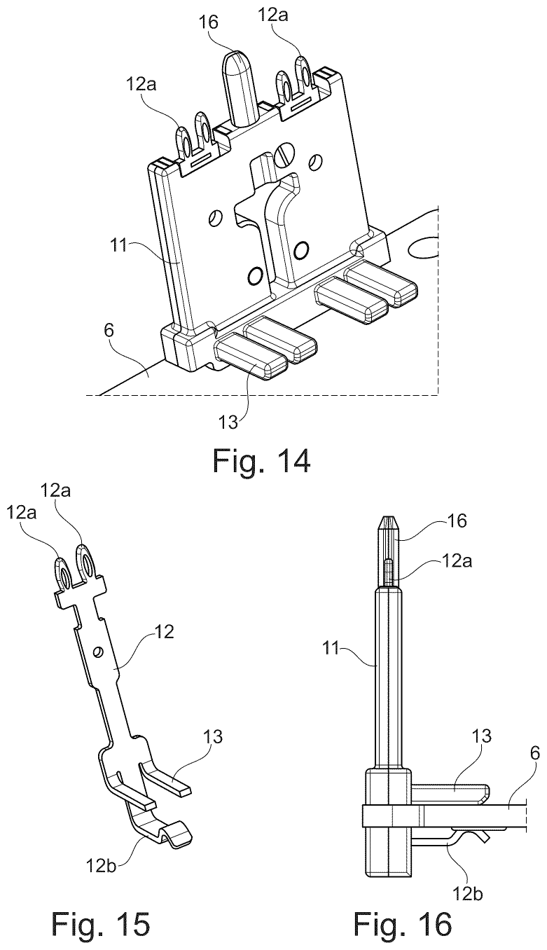

FIGS. 14 and 16 show a further embodiment of an electrical connector 10, together with a detail of the heating plate 6, in differing views. In this example of embodiment, the heating plate 6 is clamped between an end section 12b of the conductor 12 projecting from the plastic body 11, and a clamping part 13, which is formed in the plastic body 11. To improve the mechanical load-bearing capacity, the clamping part 13 formed in the plastic body 11 can contain sheet metal, for example, a clamping sheet 13 that is formed integrally with the conductor, as shown in FIG. 15, or a separate clamping sheet.

In its external appearance the embodiment shown in FIG. 14 largely corresponds to the connector 10 shown in FIG. 10, but differs in the design of the clamping part 13.

If the clamping part 13 is formed as part of the plastic body 11 of the electrical connector 10, and contains sheet metal to improve its load-bearing capacity, the plastic body 11 can cover an upper side of this sheet metal facing away from the heating plate 6, or can even enclose the clamping sheet 13 completely.

While exemplary embodiments have been disclosed hereinabove, the present invention is not limited to the disclosed embodiments. Instead, this application is intended to cover any variations, uses, or adaptations of this disclosure using its general principles. Further, this application is intended to cover such departures from the present disclosure as come within known or customary practice in the art to which this invention pertains and which fall within the limits of the appended claims.

### LIST OF REFERENCE SYMBOLS

1 Housing
2 Inlet port
3 Outlet port
4 Electrical terminal
5 Electrical terminal
6 Heating plate
6a Metal plate
6b Heating conductor track
6c Insulating layer
7 Corrugated metal sheet
8 Circuit board
10 Connector
11 Plastic body
11a Body part of the plastic body
11b Body part of the plastic body
12 Conductor
12a Press-fit contact
12b End section of the conductor
13 Clamping part
14 Bent section
15 Opening
16 Projection

What is claimed is:

1. A flow heater, comprising:
a heating plate comprising a metal plate, a heating conductor track, and an insulating layer between the heating conductor track and the metal plate;
a housing in which the heating plate is arranged, wherein the housing encloses a flow channel for fluid to be heated, which leads from an inlet port of the housing to an outlet port of the housing;
a circuit board with control electronics; and
an electrical connector connecting the heating conductor track of the heating plate electrically to the control electronics, said electrical connector comprising a plastic body from which a conductor projects and extends into a hole of the circuit board;
wherein the heating plate is clamped between a clamping part of the electrical connector and an end section of the conductor projecting from the plastic body.

2. The flow heater according to claim 1, wherein the clamping part contains sheet metal.

3. The flow heater according to claim 2, wherein a first end section of the metal sheet of the clamping part, or the metal sheets of the clamping part, abuts against the heating plate, and a second end section of the metal sheet, or the metal sheets, of the clamping part is arranged in the plastic body.

4. The flow heater according to claim 1, wherein the plastic body comprises a first body part, which abuts against the heating plate, and a second body part, from which the end section of the conductor plugged into the circuit board projects, wherein the first body part and the second body part are plugged together.

5. The flow heater according to claim 1, wherein the conductor is formed by a continuous metal strip, wherein the metal strip has a first end section which is inserted in the circuit board and has a second end section, which abuts against the heating plate.

6. The flow heater according to claim 1, wherein the electrical connector has two or more clamping parts, and the heating plate is clamped between the clamping parts and the end section of the conductor.

7. The flow heater according to claim 1, wherein the plastic body is inserted into a recess in the heating plate, and has a groove on opposite sides, in which the heating plate is seated.

8. The flow heater according to claim 1, wherein the conductor forms one or a plurality of press-fit contacts, which are inserted in the circuit board.

9. The flow heater according to claim 1, wherein the conductor abuts against the heating plate with a bent section.

10. The flow heater according to claim 1, wherein the conductor is a sheet metal part that has been produced by a cutting process.

11. A flow heater, comprising:
a heating plate comprising a metal plate, a heating conductor track, and an insulating layer between the heating conductor track and the metal plate;
a housing in which the heating plate is arranged, wherein the housing encloses a flow channel for fluid to be heated, which leads from an inlet port of the housing to an outlet port of the housing;
a circuit board with control electronics; and
an electrical connector connecting the heating conductor track of the heating plate electrically to the control electronics, said electrical connector comprising a plastic body from which a conductor projects and extends into a hole of the circuit board;
wherein the heating plate is clamped between a clamping part of the electrical connector and an end section of the conductor projecting from the plastic body; and
wherein said clamping part is made of a strip of sheet metal that protrudes from the plastic body and in electrically isolated from the conductor.

12. A heating plate for a flow heater, comprising:
a metal plate;
a heating conductor track;
an insulating layer between the heating conductor track and the metal plate; and
an electrical connector configured for connecting the heating plate to a circuit board, wherein the connector has a plastic body, from which a conductor protrudes, which terminates in a contact for insertion into a hole of a circuit board, wherein a clamping sheet projects from the plastic body, and the heating plate is connected between the clamping sheet and an end section projecting from the plastic body, and the heating plate is clamped between the clamping sheet and an end section of the conductor projecting from the plastic body.
